(19) United States
(12) Patent Application Publication
(10) Pub. No.: US 2020/0127174 A1
(43) Pub. Date: Apr. 23, 2020

(54) LIGHT EMITTING DIODE PACKAGE WITH ENHANCED QUANTUM DOT RELIABILITY

(71) Applicant: Lextar Electronics Corporation, Hsinchu (TW)

(72) Inventors: Chang-Zhi ZHONG, Hsinchu County (TW); Hung-Chun TONG, New Taipei City (TW); Yu-Chun LEE, Hsinchu County (TW); Tzong-Liang TSAI, Taichung City (TW)

(21) Appl. No.: 16/198,890

(22) Filed: Nov. 23, 2018

(30) Foreign Application Priority Data
Oct. 22, 2018 (TW) 107137240

(51) Int. Cl. H01L 33/50; H01L 33/58; H01L 33/60

(52) U.S. Cl. CPC H01L 33/504; H01L 33/60; H01L 33/58; H01L 33/505

(57) ABSTRACT

A light emitting diode package includes a light emitting diode chip, a wavelength conversion layer, and a light attenuating layer. The light emitting diode chip emits a first light. The wavelength conversion layer includes a plurality of quantum dots. The light attenuating layer is disposed between the light emitting diode chip and the wavelength conversion layer. The light attenuating layer is configured to attenuate an intensity of the first light beam and then emits a second light beam which will be partially absorbed by the quantum dots. A wavelength of the first light beam is substantially the same wavelength of the second light beam.

### CROSS-REFERENCE TO RELATED APPLICATION

This application claims priority to Taiwan Application Serial Number 107137240, filed Oct. 22, 2018, which is herein incorporated by reference in its entirety.

### BACKGROUND

### Field of Invention

The present disclosure relates to a light emitting diode package. More particularly, the present disclosure relates to a light emitting diode package with enhanced quantum dot reliability.

### Description of Related Art

Nowadays, common materials used for light emitting are phosphors and quantum dots. Quantum dots have very narrow full width at half maximum (FWHM) and broad color gamut which have not been achieved by traditional phosphors. The extremely small size of the quantum dots leads to discrete energy states, which results in unique optoelectronic properties thereof. The energy band gap of the quantum dots can be adjusted by controlling their size. For example, the quantum dots having a larger size have a narrower band gap, and the quantum dots having a smaller size have a wider band gap. That is to say, the smaller the size of the quantum dots, the shorter the wavelength of the emitted light, and the greater the size of the quantum dots, the greater the wavelength of the emitted light. Therefore, high color quality light can be emitted by quantum dots via controlling their size.

However, a major limitation of quantum dots is that they have the poor photo-stability. Therefore, there is an urgent request for increasing the life of the quantum dots in quantum dots applications.

### SUMMARY

Some embodiments of the present disclosure provide a light emitting diode package. A light attenuating layer is disposed between the wavelength conversion layer and the light emitting diode chip. The light attenuating layer can allow the first light beam emitted by the light emitting diode chip become a second light beam having a light intensity lower than a light intensity of the first light beam, which then transmits to the wavelength conversion layer. Therefore, the quantum dots in the wavelength conversion layer can be prevented from being completely irradiated by direct exposure to high photon flux from the first light beam and results in the enhanced quantum dot reliability.

In some embodiments, a light emitting diode package includes a light emitting diode chip, a wavelength conversion layer, and a light attenuating layer. The light emitting diode chip emits a first light beam. A wavelength conversion layer includes a plurality of quantum dots. A light attenuating layer is disposed between the light emitting diode chip and the wavelength conversion layer. The light attenuating layer is configured to attenuate a light intensity of the first light beam and then emit a second light beam which will be partially absorbed by the quantum dots. A wavelength of the first light beam is substantially the same as a wavelength of the second light beam.

In some embodiments, the light attenuating layer includes a plurality of first particles configured to absorb the first light beam to attenuate the light intensity of the first light beam, and a remaining portion of the first light beam becomes the second light beam.

In some embodiments, a diameter of each of the first particles is greater than a diameter of each of the quantum dots.

In some embodiments, a weight percentage of the first particles in the light attenuating layer is from about 1% to about 90%, and a weight percentage of the quantum dots in the wavelength conversion layer is from about 0.01% to about 70%.

In some embodiments, a concentration ratio of the first particles to the quantum dots is from about 0.009 to about 9000.

In some embodiments, the first particles include a plurality of phosphor particles, the phosphor particles absorb a portion of the first light beam and emit a third light beam, the quantum dots absorb a portion of the second light beam and emit a fourth light beam, and a wavelength of the third light beam is different from a wavelength of the fourth light beam.

In some embodiments, the light attenuating layer absorbs a light having a wavelength from about 350 nm to about 650 nm and emits a light having a wavelength from about 550 nm to about 800 nm. The wavelength conversion layer absorbs a light having a wavelength from about 350 nm to about 550 nm and emits a light having a wavelength from about 480 nm to about 550 nm.

In some embodiments, the light attenuating layer includes red phosphor particles, and the wavelength conversion layer includes green quantum dots.

In some embodiments, the light attenuating layer absorbs a light having a wavelength from about 350 nm to about 570 nm and emits a light having a wavelength from about 480 nm to about 700 nm, the wavelength conversion layer absorbs a light having a wavelength from about 350 nm to about 700 nm and emits a light having a wavelength from about 550 nm to about 800 nm.

In some embodiments, the light attenuating layer includes green phosphor particles, and the wavelength conversion layer includes red quantum dots.

In some embodiments, an area of a top surface of the wavelength conversion layer is greater than an area of a top surface of the light attenuating layer.

In some embodiments, the light emitting diode package further includes a light extraction layer disposed between the light attenuating layer and the light emitting diode chip. An area of the light attenuating layer is substantially the same as an area of the wavelength conversion layer.

In some embodiments, the light emitting diode package further includes a light permeable layer disposed on the wavelength conversion layer.

In some embodiments, the light emitting diode package further includes a reflective portion comprising a reflective wall surrounding the light emitting diode chip, the light attenuating layer and the wavelength conversion layer.

In some embodiments, the light attenuating layer is in direct contact with and surrounds the light emitting diode chip.

It is to be understood that both the foregoing general description and the following detailed description are by examples, and are intended to provide further explanation of the invention as claimed.

### BRIEF DESCRIPTION OF THE DRAWINGS

The invention can be more fully understood by reading the following detailed description of the embodiment, with reference made to the accompanying drawings as follows:

FIG. 1 is a cross-sectional view of a light emitting diode package according to one embodiment;

FIG. 2 is a scheme diagram of a path of the light emitted by the light emitting diode package in FIG. 1 during actual operation;

FIG. 3 is a fluorescence spectrogram of the light emitting diode package according to one embodiment;

FIG. 4 is a fluorescence spectrogram of the light emitting diode package according to one embodiment;

FIG. 5 is a cross-sectional view of a light emitting diode package according to another embodiment;

FIG. 6 is a scheme diagram of a path of the light emitted by the light emitting diode package in FIG. 5 during actual operation;

FIG. 7 is a time-related fluorescence spectrogram of the light emitting diode package in FIG. 5;

FIG. 8 is a cross-sectional view of the light emitting diode package of the prior art; and

FIG. 9 is a time-related fluorescence spectrogram of to the light emitting diode package in FIG. 8.

### DETAILED DESCRIPTION

Reference will now be made in detail to the present embodiments of the invention, examples of which are illustrated in the accompanying drawings. Wherever possible, the same reference numbers are used in the drawings and the description to refer to the same or like parts.

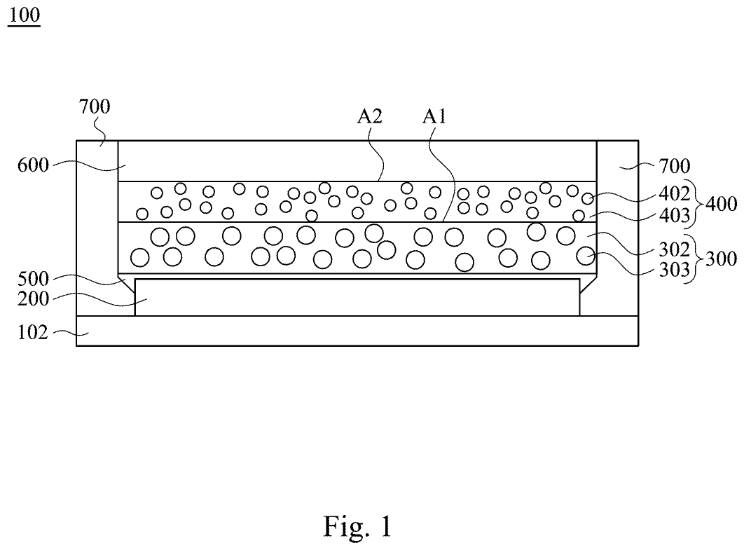

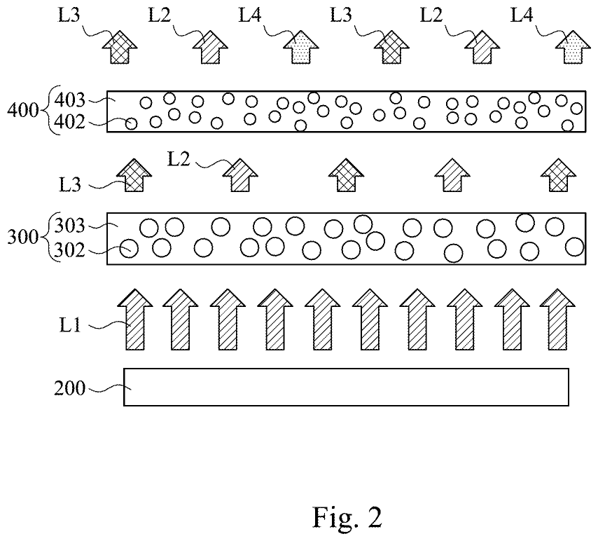

FIG. 1 is a cross-sectional view of a light emitting diode package 100 according to one embodiment of the present disclosure. FIG. 2 is a scheme diagram of a path of the light emitted by the light emitting diode package 100 in FIG. 1 during actual operation. Reference is made to FIGS. 1 and 2. The light emitting diode package 100 includes a substrate 102, a light emitting diode chip 200, a light attenuating layer 300, a wavelength conversion layer 400, a light extraction layer 500, and a light permeable layer 600. The light extraction layer 500 is disposed between the light attenuating layer 300 and the light emitting diode chip 200. The light attenuating layer 300 is disposed between the light emitting diode chip 200 and the wavelength conversion layer 400. The light permeable layer 600 is disposed on the wavelength conversion layer 400. The light emitting diode package 100 has a reflective portion 700. The reflective portion 700 surrounds the light emitting diode chip 200, the light attenuating layer 300, the wavelength conversion layer 400, the light extraction layer 500, and the light permeable layer 600. An area A1 of the light attenuating layer 300 is substantially the same as an area A2 of the wavelength conversion layer 400. The light emitting diode chip 200 is electrically connected to the substrate 102.

In one embodiment, the wavelength conversion layer 400 includes a plurality of quantum dots 402 and a transparent colloid 403. The transparent colloid 403 of the wavelength conversion layer 400 can be polymethyl methacrylate (PMMA), polyethylene terephthalate (PET), polystyrene (PS), polypropylene (PP), polyamide (PA), polycarbonate (PC), polyimide (PI), polydimethylsiloxane (PDMS), epoxy, silicone, the like, or combinations thereof. The wavelength conversion layer 400 can further include an inorganic filler, for example, titanium dioxide (TiO₂), silicon dioxide (SiO₂), boron nitride (BN), zirconium oxide (ZnO), the like, or combinations thereof.

A first light beam L1 generated by the light emitting diode chip 200 passes through the light extraction layer 500 and arrives at the light attenuating layer 300. In one embodiment, the light extraction layer 500 can be an adhesive layer configured to adhere the light emitting diode chip 200 to the light attenuating layer 300. The light extraction layer 500 includes an organic colloid, for example, PMMA, PET, PEN, PS, PP, PA, PC, PI, epoxy, silicone, the like, or combinations thereof; and an inorganic filler, for example, TiO₂, SiO₂, BN, ZnO, the like, or combinations thereof. In one embodiment, the light permeable layer 600 includes glass or glass composite doped with at least one metal. In one embodiment, the light permeable layer 600 includes an organic material, an inorganic material, the like, or combinations thereof. In one embodiment, the light permeable layer 600 includes an organic colloid, for example, PMMA, PET, PEN, PS, PP, PA, PC, PI, epoxy, silicone, the like, or combinations thereof; and an inorganic filler, for example, TiO₂, SiO₂, BN, ZnO, the like, or combinations thereof.

The quantum dot 402 includes group II-VI compound semiconductor, such as CdSe, CdTe, ZnS, ZnSe, ZnTe, ZnO, HgS, HgSe, HgTe, CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, CdZnSeS, CdZnSeTe, CdZnSTe, CdHgSeS, CdHgSeTe, CdHgSTe, HgZnSeS, HgZnSeTe, HgZnSTe; group III-V compound semiconductor, such as GaN, GaP, GaAs, GaSb, AlN, AlP, AlAs, AlSb, InN, InP, InAs, InSb, GaNP, GaNAs, GaNSb, GaPAs, GaPSb, AlNP, AlNAs, AlNSb, AlPAs, AlPSb, InNP, InNAs, InNSb, InPAs, InPSb, GaAlNP, GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, InAlPSb; group IV-VI compound semiconductor, such as SnS, SnSe, SnTe, PbS, PbSe, PbTe, SnSeS, SnSeTe, SnSTe, PbSeS, PbSeTe, PbSTe, SnPbS, SnPbSe, SnPbTe, SnPbSSe, SnPbSeTe, SnPbSTe; or group IV semiconductor, such as Si, and halide perovskite (CsPbX₃ or Cs₄PbX₆, X═CI, Br, I, or combinations thereof), which can generate light having different colors by controlling the ratio of Cl, Br and I.

In one embodiment, the quantum dot 402 can be physically or chemically modified or protected. For example, the quantum dot 402 can be a core-shell structure, have silica coating or SiTiO₄₋ₓ coating, be formed via a ligand exchange process, microemulsion, or polymer encapsulation, be in the pores of mesoporous material, the like, or formed by the combinations thereof.

The light emitting diode chip 200 emits a first light beam L1. The light attenuating layer 300 is configured to attenuate the first light beam L1 emitted by the light emitting diode chip 200 and in turn emits a second light beam L2 to be absorbed by the quantum dots 402. In some embodiments, a wavelength of the first light beam L1 is substantially the same as a wavelength of the second light beam L2. In particular, still referring to FIG. 2, the light attenuating layer 300 includes a plurality of first particles 302 configured to absorb a portion of the first light beam L1 to reduce a light intensity of the first light beam L1. A remaining portion of the first light beam L1 after passing through the light attenuating layer 300 is referred to as the second light beam L2 and then transmits into the wavelength conversion layer 400. In one embodiment, a diameter of the first particle 302 is greater than a diameter of the quantum dot 402. For example, the first particles 302 include a plurality of phosphor particles. The first particles 302 can absorb a portion of the first light beam L1 and emit a third light beam L1 to pass through the wavelength conversion layer 400. The quantum dots 402 absorb a portion of the second light beam L2 and emit a fourth light beam L4. A wavelength of the third light beam L3 is different from a wavelength of the fourth light beam L4.

In particular, the light attenuating layer 300 includes a plurality of first particles 302 and the transparent colloid 303, such as PMMA, PET, PEN, PS, PP, PA, PC, PI, epoxy, silicone, the like, or combinations thereof, and an inorganic filler, such as TiO₂, SiO₂, BN, ZnO, the like, or combinations thereof. The first particles 302 can include phosphor particles, such as LuYAG, GaYAG, YAG, silicate (e.g., Ba₂SiO₄:Eu²⁺, Sr₂SiO₄:Eu²⁺, (Mg,Ca,Sr,Ba)₃Si₂O₇:Eu²⁺, Ca₈Mg(SiO₄)₄C1₂:Eu²⁺(CS), (Mg,Ca,Sr,Ba)₂SiO₄:Eu²⁺), SLA, KSF, SILION, sulfide (e.g., SrS:Eu²⁺, SrGa₂S₄:Eu²⁺, ZnS:Cu⁺, ZnS:Ag⁺, Y₂O₂S:Eu²⁺, La₂O₂S:Eu²⁺, Gd₂O₂S:Eu²⁺, SrGa₂S₄:Ce³⁺, ZnS:Mn²⁺, SrS:Eu²⁺, CaS:Eu²⁺, (Sr₁₋ₓCaₓ)S:Eu²⁺), nitride (e.g., (Ca,Mg,Y)Si_{w}AlₓO_{y}N_{z}:Ce²⁺, Ca₂Si₅N₈:Eu²⁺, (Ca,Mg,Y)Si_{w}AlₓO_{y}N_{z}:Eu²⁺, (Sr,Ca,Ba)SiₓO_{y}N_{z}:Eu²⁺), or fluoride (e.g., fluosilicate (K₂SiF₆:Mn⁴⁺; KSF), fluotitanate (K₂TiF₆:Mn⁴⁺; KTF), fluogermanate (K₂GeF₆:Mn⁴⁺; KGF)).

In one embodiment, a weight percentage of the first particles 302 in the light attenuating layer 300 is from about 1% to about 90%. In some other embodiments, the weight percentage of the first particles 302 in the light attenuating layer 300 is from about 5% to about 80%. In one embodiment, a weight percentage of the quantum dots 402 in the wavelength conversion layer 400 is from about 0.01% to about 70%. In some other embodiments, a weight percentage of the quantum dots 402 in the wavelength conversion layer 400 is from about 0.05% to about 60%. The concentration ratio of the first particles 302 to the quantum dots 402 is from about 0.009 to about 9000. The ratio of the first particles 302 to the quantum dots 402 can be designed based on the requirement of the products.

In one embodiment, the light emitting diode chip 200 is a blue light emitting diode chip, the first particles 302 of the light attenuating layer 300 are red phosphor particles, and the quantum dots 402 of the wavelength conversion layer 400 are green quantum dots. The first light beam L1 emitted by the light emitting diode chip 200 has a wavelength in a range from about 350 nm to about 480 nm. The red phosphor particles in the light attenuating layer 300 is configured to absorb a light having a wavelength from about 350 nm to about 650 nm. Therefore, the red phosphor particles absorb a portion of the first light beam L1 to reduce a light intensity of the first light beam L1. A remaining portion of the first light beam L1 passing through the light attenuating layer 300 is referred to as the second light beam L2. The wavelength of the first light beam L1 is substantially the same as the wavelength of the second light beam L2. In particular, the red phosphor particles absorb a portion of the first light beam L1 and transform the first light beam L1 into the third light beam L3. The wavelength of the third light beam L3 is from about 550 nm to about 800 nm. The green quantum dots in the wavelength conversion layer 400 is configured to absorb a light having a wavelength from about 350 nm to about 550 nm. Therefore, the green quantum dots can absorb a portion of the second light beam L2 from the light attenuating layer 300 and transform the second light beam L2 into the fourth light beam L4. The wavelength of the fourth light beam L4 is from about 480 nm to about 550 nm. In particular, the red phosphor particles include fluoride, such as A₂[MF₆]:Mn⁴⁺ (A is selected from a group consisted of Li, Na, K, Rb, Cs, NH₄, the like, or combinations thereof, and M is selected from a group consisting of Ge, Si, Sn, Ti, Zr, the like, or combinations thereof). Moreover, the red phosphor particles can include, but is not limited to, (Sr,Ca)S:Eu, (Ca,Sr)₂Si₅N₈:Eu, CaAlSiN₃:Eu, (Sr,Ba)₃SiO₅:Eu, the like, or combinations thereof. The green quantum dots can include, but is not limited, CdSe, perovskite quantum dots (e.g., CsPb(Br_{1-b}I_{b})₃, in which 0≤b<0.5), the like, or combinations thereof.

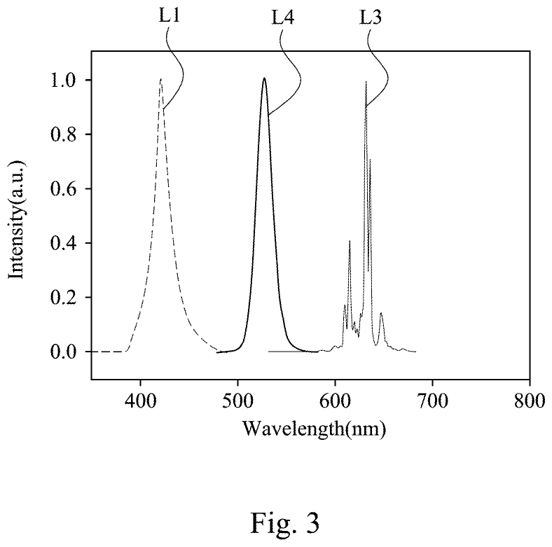

FIG. 3 is a fluorescence spectrogram of the light emitting diode package according to one embodiment. FIG. 3 is a fluorescence spectrogram of the light emitting diode package 100 in FIG. 2 where the first particles 302 in the light attenuating layer 300 are red phosphor particles (e.g., K₂SiF₆:Mn⁴⁺) absorbing the first light beam L1 and emitting the third light beam L3, and the quantum dots 402 in the wavelength conversion layer 400 are green quantum dots (e.g., CdSe) absorbing the second light beam L2 and emitting the fourth light beam L4. Reference is made to FIGS. 2 and 3. The red phosphor particles in the light attenuating layer 300 absorb and transform a portion of the first light beam L1 and in turn emit the third light beam L3. The wavelength of the third light beam L3 is from about 550 nm to about 800 nm. The green quantum dots in the wavelength conversion layer 400 absorb and transform a portion of the second light beam L2 (the wavelength of the second light beam L2 is substantially the same as the wavelength of the first light beam L1, and he light intensity of the second light beam L2 is less than the light intensity of the first light beam L1) and in turn emit the fourth light beam L4. The wavelength of the fourth light beam L4 is different from the wavelength of the third light beam L3. For example, the wavelength of the fourth light beam L4 is from about 480 nm to about 550 nm. Therefore, by mixing the remaining second light beam L2, the third light beam L3, and the fourth light beam L4, the light emitting diode package 100 can emit white light.

In some other embodiments, the light emitting diode chip 200 is a blue light emitting diode chip, the first particles 302 of the light attenuating layer 300 are green phosphor particles, and the quantum dots 402 of the wavelength conversion layer 400 are red quantum dots. The first light beam L1 emitted by the light emitting diode chip 200 has a wavelength in a range from about 350 nm to about 480 nm. The green phosphor particles in the light attenuating layer 300 is configured to absorb a light having a wavelength from about 350 nm to about 570 nm. Therefore, the green phosphor particles absorb a portion of the first light beam L1 to reduce the light intensity of the first light beam L1. The remaining portion of the first light beam L1 passing through the light attenuating layer 300 is referred to as the second light beam L2. The wavelength of the first light beam L1 is substantially the same as the wavelength of the second light beam L2. In particular, the green phosphor particles absorb a portion of the first light beam L1 and transform the first light beam into the third light beam L3. The wavelength of the third light beam L3 is from about 480 nm to about 700 nm. The red quantum dots in the wavelength conversion layer 400 is configured to absorb a light having a wavelength from about 350 nm to about 700 nm. Therefore, the red quantum dots can absorb a portion of the second light beam L2 from the light attenuating layer 300 and transform the second light beam L2 into the fourth light beam L4. The wavelength of the fourth light beam L4 is from about 550 nm to about 800 nm. In particular, the green phosphor particles include, but is not limited to, Beta-SiAlON (Si_{6-z}Al_{z}O_{z}N_{8-z}:Eu²⁺) or the like. The red quantum dots can include, but is not limited to, CdSe, perovskite quantum dots, such as CsPb(Br_{1-b}I_{b})₃, in which 0.5≤b≤1, or the like.

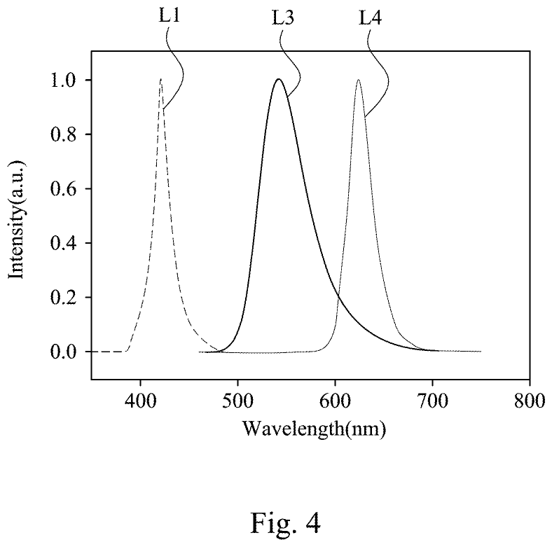

FIG. 4 is a fluorescence spectrogram of the light emitting diode package according to one embodiment. FIG. 4 is a fluorescence spectrogram of the light emitting diode package 100 in FIG. 2 where the first particles 302 in the light attenuating layer 300 are green phosphor particles (e.g., Beta-SiAlON) absorbing the first light beam L1 and in turn emitting the third light beam L3, and the quantum dots 402 in the wavelength conversion layer 400 are red quantum dots (e.g., CdSe) absorbing the second light beam L2 and in turn emitting the fourth light beam L4. Reference is made to FIGS. 2 and 4. The green phosphor particles in the light attenuating layer 300 absorb and transform a portion of the first light beam L1 and in turn emit the third light beam L3. The wavelength of the third light beam L3 is from about 480 nm to about 700 nm. The red quantum dots in the wavelength conversion layer 400 absorb and transform a portion of the second light beam L2 (the wavelength of the second light beam L2 is substantially the same as the wavelength of the first light beam L1, and the light intensity of the second light beam L2 is less than the light intensity of the first light beam L1) and in turn emit the fourth light beam L4. The wavelength of the fourth light beam L4 is different from the wavelength of the third light beam L3. For example, the wavelength of the fourth light beam L4 is from about 550 nm to about 800 nm. Therefore, by mixing the remaining second light beam L2, the third light beam L3, and the fourth light beam L4, the light emitting diode package 100 can emit white light.

Since the quantum dots have the poor photo-stability, the first light beam L1 emitted by the light emitting diode chip 200 is transformed into the second light beam L2 having the light intensity less than the light intensity of the first light beam L1 and in turn arriving at the wavelength conversion layer 400 (see FIGS. 1 and 2). Therefore, the quantum dots 402 in the wavelength conversion layer 400 can be prevented from being completely irradiated by direct exposure to high photon flux from the first light beam L1 (e.g., the blue light), which results in the enhanced quantum dot reliability.

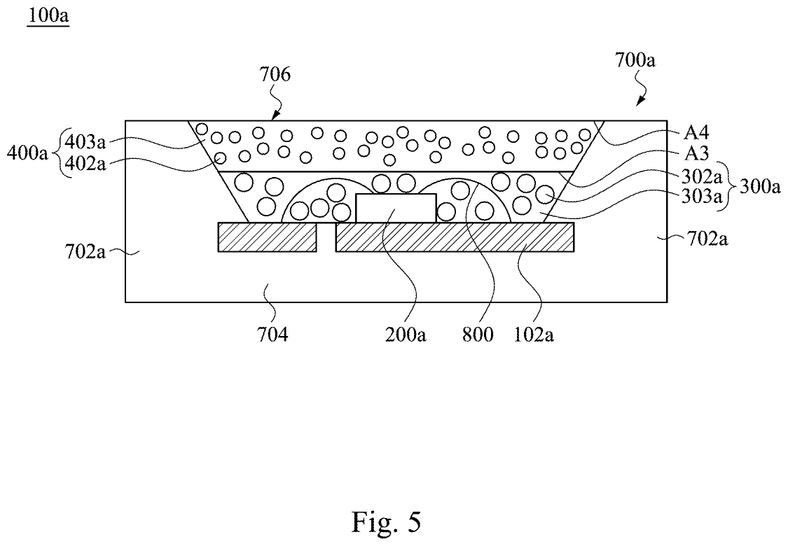

FIG. 5 is a cross-sectional view of a light emitting diode package 100a according to another embodiment of the present disclosure. The light emitting diode package 100a includes a substrate 102a, a reflective portion 700a, a light emitting diode chip 200a, a light attenuating layer 300a, and a wavelength conversion layer 400a. The light attenuating layer 300a includes first particles 302a and a transparent colloid 303a. The wavelength conversion layer 400a includes quantum dots 402a and a transparent colloid 403a. The reflective portion 700a includes a reflective wall 702a and a base 704. An inner surface of the reflective wall 702a is an inclined reflective surface. The reflective wall 702a and the base 704 define an accompanying space 706. The accompanying space 706 has a top width and a bottom width narrower than the top width. The light emitting diode chip 200a, the light attenuating layer 300a, and the wavelength conversion layer 400a is in the accompanying space 706. The reflective wall 702a surrounds the light emitting diode chip 200a, the light attenuating layer 300a, and the wavelength conversion layer 400a. An area A4 of a top surface of the wavelength conversion layer 400a is greater than an area A3 of a top surface of the light attenuating layer 300a.

The reflective portion 700a encapsulates a portion of the substrate 102a. The light emitting diode chip 200a is disposed on the top surface of the substrate 102a and electrically connected to the positive and negative electrodes of the substrate 102a by the wires 800 such that the light emitting diode chip 200a can receive the electrical current and emit light.

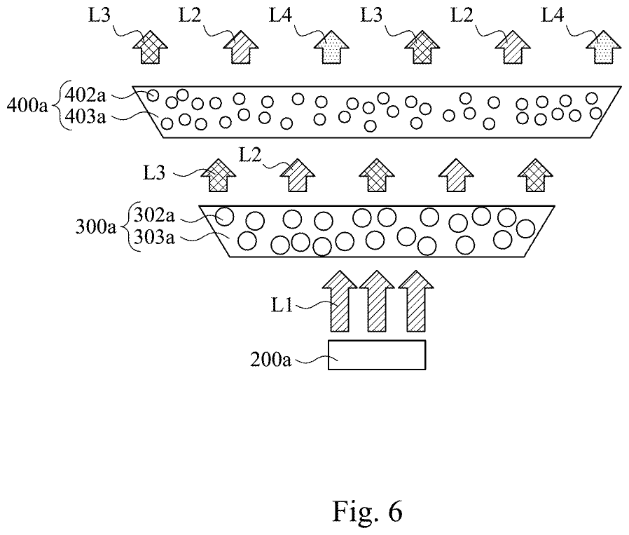

The light attenuating layer 300a is in direct contact with and surrounds the light emitting diode chip 200a. The light attenuating layer 300a has a top width and a bottom width narrower than the top width. Reference is made to FIG. 6. Therefore, an emitting area of the second light beam L2 is greater than an emitting area of the first light beam L1, which is beneficial for reducing the light intensity of the second light beam L2. The quantum dots 402a are irradiated by the second light beam L2 with the reduced light intensity such that the reliability of the quantum dots 402a are enhanced. In particular, the first light beam L1 emitted by the light emitting diode chip 200a becomes the second light beam L2 having the light intensity less than the first light beam L1 by passing through the light attenuating layer 300a and then arrives at the wavelength conversion layer 400a, which prevents the quantum dots 402 from being directly irradiated by the first light beam L1, such that a reliability of the quantum dots 402a is enhanced. It is noted that, the elements and relations therebetween in the abovementioned embodiments will not be repeated herein.

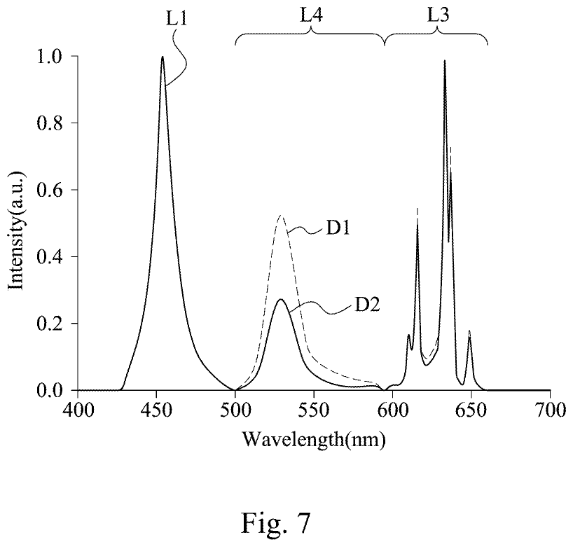

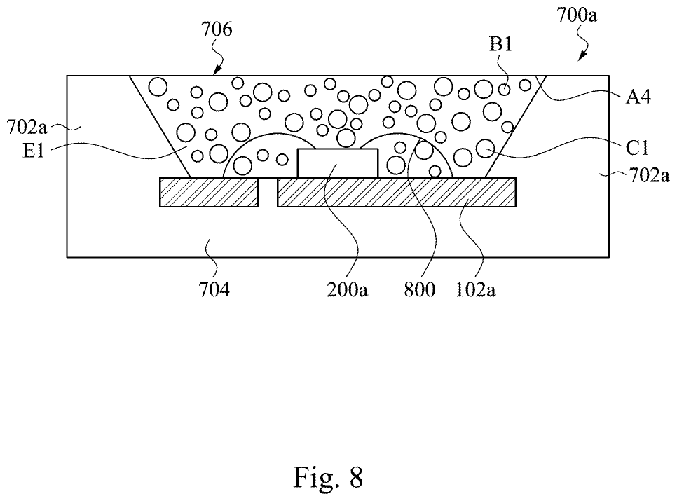

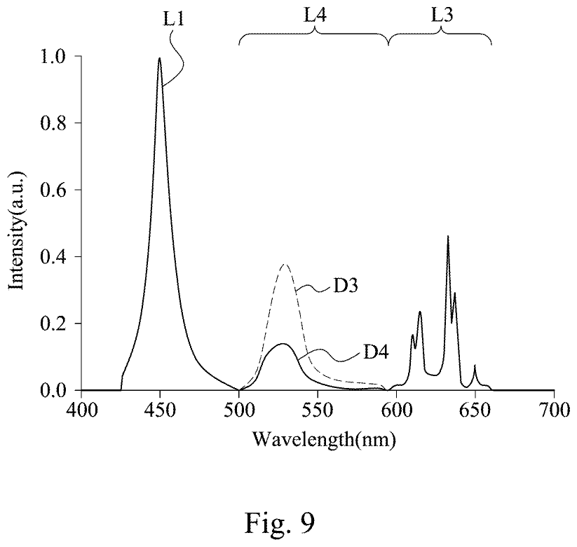

FIG. 7 is a time-related fluorescence spectrogram of the light emitting diode package 100a in FIG. 5. In one embodiment, the first particles 302a of the light emitting diode package 100a are red phosphor particles, and the quantum dots 402a are green quantum dots. The quantum dots 402a emit the fourth light beam L4 having a wavelength in a range from about 480 nm to about 550 nm. A curve D1 is an original fluorescence spectrogram of the light emitting diode package 100a. A curve D2 is a fluorescence spectrogram of the light emitting diode package 100a after about 576 hours. As shown in FIG. 7, after about 576 hours, a light intensity of the curve D2 becomes about 49% of a light intensity of the curve D1. FIG. 8 is a cross-sectional view of the light emitting diode package of the prior art. The difference between the prior art and the present embodiment is that the green quantum dots B1 and the red phosphor particles C1 are both distributed in a colloid E1. FIG. 9 is a time-related fluorescence spectrogram of to the light emitting diode package in FIG. 8. A curve D3 is an original fluorescence spectrogram of the light emitting diode package. A curve D4 is a fluorescence spectrogram of the light emitting diode package after about 576 hours. As shown in FIG. 9, after about 576 hours, a light intensity of the curve D4 becomes about 66% of a light intensity of the curve D3. Compare FIG. 7 with FIG. 9, the reduction amplitude of the curve D2 of the present embodiment is less than the reduction amplitude of the curve D4 of the prior art. The quantum dots 402a of the present embodiments has enhanced reliability compared to the green quantum dots B1 of the prior art.

By disposing the light attenuating layer between the wavelength conversion layer and the light emitting diode chip in the light emitting diode package, the light attenuating layer can transform the first light beam emitted by the light emitting diode chip into the second light beam having the light intensity less than the light intensity of the first light beam, which then transmits to the wavelength conversion layer. Therefore, the quantum dots in the wavelength conversion layer can be prevented from being completely irradiated by direct exposure to high photon flux from the first light beam such that the quantum dot reliability is enhanced.

Although the present invention has been described in considerable detail with reference to certain embodiments thereof, other embodiments are possible. Therefore, the spirit and scope of the appended claims should not be limited to the description of the embodiments contained herein.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims.

What is claimed is:

1. A light emitting diode package, comprising:
a light emitting diode chip emitting a first light beam;
a wavelength conversion layer including a plurality of quantum dots; and
a light attenuating layer disposed between the light emitting diode chip and the wavelength conversion layer, wherein the light attenuating layer is configured to attenuate a light intensity of the first light beam and then emit a second light beam which will be partially absorbed by the quantum dots, and a wavelength of the first light beam is substantially the same as a wavelength of the second light beam.

2. The light emitting diode package of claim 1, wherein the light attenuating layer includes a plurality of first particles configured to absorb the first light beam to attenuate the light intensity of the first light beam, and a remaining portion of the first light beam becomes the second light beam.

3. The light emitting diode package of claim 2, wherein a diameter of each of the first particles is greater than a diameter of each of the quantum dots.

4. The light emitting diode package of claim 2, wherein a weight percentage of the first particles in the light attenuating layer is from about 1% to about 90%, and a weight percentage of the quantum dots in the wavelength conversion layer is from about 0.01% to about 70%.

5. The light emitting diode package of claim 2, wherein a concentration ratio of the first particles to the quantum dots is from about 0.009 to about 9000.

6. The light emitting diode package of claim 2, wherein the first particles include a plurality of phosphor particles, the phosphor particles absorb a portion of the first light beam and emit a third light beam, the quantum dots absorb a portion of the second light beam and emit a fourth light beam, and a wavelength of the third light beam is different from a wavelength of the fourth light beam.

7. The light emitting diode package of claim 1, wherein the light attenuating layer absorbs a light having a wavelength from about 350 nm to about 650 nm and emits a light having a wavelength from about 550 nm to about 800 nm, and the wavelength conversion layer absorbs a light having a wavelength from about 350 nm to about 550 nm and emits a light having a wavelength from about 480 nm to about 550 nm.

8. The light emitting diode package of claim 7, wherein the light attenuating layer includes red phosphor particles, and the wavelength conversion layer includes green quantum dots.

9. The light emitting diode package of claim 1, wherein the light attenuating layer absorbs a light having a wavelength from about 350 nm to about 570 nm and emits a light having a wavelength from about 480 nm to about 700 nm, and the wavelength conversion layer absorbs a light having a wavelength from about 350 nm to about 700 nm and emits a light having a wavelength from about 550 nm to about 800 nm.

10. The light emitting diode package of claim 9, wherein the light attenuating layer includes green phosphor particles, and the wavelength conversion layer includes red quantum dots.

11. The light emitting diode package of claim 1, wherein an area of a top surface of the wavelength conversion layer is greater than an area of a top surface of the light attenuating layer.

12. The light emitting diode package of claim 1, further comprising a light extraction layer disposed between the light attenuating layer and the light emitting diode chip, wherein an area of the light attenuating layer is substantially the same as an area of the wavelength conversion layer.

13. The light emitting diode package of claim 1, further comprising a light permeable layer disposed on the wavelength conversion layer.

14. The light emitting diode package of claim 1, further comprising:
a reflective portion comprising a reflective wall surrounding the light emitting diode chip, the light attenuating layer and the wavelength conversion layer.

15. The light emitting diode package of claim 1, wherein the light attenuating layer is in direct contact with and surrounds the light emitting diode chip.
